(19) United States
(12) Patent Application Publication
(10) Pub. No.: US 2008/0297227 A1
(43) Pub. Date: Dec. 4, 2008

(54) INTEGRATED CIRCUIT SYSTEM FOR ANALOG SWITCHING

(75) Inventor: Philip W. Yee, Los Altos, CA (US)

Correspondence Address: LAW OFFICES OF MIKIO ISHIMARU, 333 W. EL CAMINO REAL, SUITE 330, SUNNYVALE, CA, 94087, US

(73) Assignee: MICREL, INC., San Jose, CA (US)

(21) Appl. No.: 12/044,847

(22) Filed: Mar. 7, 2008

Related U.S. Application Data
(60) Provisional application No. 60/941,108, filed on May 31, 2007.

(51) Int. Cl. H03K 17/00

(52) U.S. Cl. 327/408

(57) ABSTRACT

An integrated circuit system comprising: forming an analog switch including: providing a current source for driving the analog switch, coupling a first source follower to the current source for forming a first input to the analog switch, coupling a second source follower to the current source for forming a second input to the analog switch, and coupling a switch to the first source follower and the second source follower for selecting the first input, the second input, or a combination thereof; and selecting a voltage output signal from the first source follower, the second source follower, or a combination thereof including isolating the first input from the second input.

### CROSS-REFERENCE TO RELATED APPLICATION

This application claims the benefit of U.S. Provisional Patent Application Ser. No. 60/941,108 filed May 31, 2007, and the subject matter thereof is hereby incorporated herein by reference thereto.

### TECHNICAL FIELD

The present invention relates generally to integrated circuits, and more particularly to a system for performing analog switching in integrated circuits.

### BACKGROUND ART

Modern electronics, such as smart phones and personal digital assistants, are packing more integrated circuit functions into an ever-shrinking physical space with expectations for decreasing cost. In order to facilitate these requirements, several functions may reside within the device. These functions may include wireless internet access, a camera, address book, or a data storage and retrieval system. Each of these functions will share the same user interface controls for their operation. The switching mechanism required for the interface exchange may be larger and more costly than the individual functions themselves.

There are several areas of concern associated with an analog switch, such as a source follower analog switch, where the input can be switched between a first voltage input (Vin1) and a second voltage input (Vin2). The analog switch may have common mode requirements that require the two input signals to be biased to the same voltage. This is done to prevent uncontrollable signal swings on the output of the switch. Quite often the circuitry required to prepare a signal to be switched is more significant than the switch itself.

The input of the switch must operate at Vin1 and Vin2. Since these levels are variable, a full transmission gate must be used in the implementation. In a CMOS design this involves both a P-channel transistor and a parallel N-channel transistor with associated logic for driving the parallel transistors.

As an analog switch turns on or off an amount of charge can be capacitively coupled or injected from the digital control line to the analog signal path. Since the input to the switch is tied directly to the gate of the source follower, voltage induced from charge injection may propagate directly to an output voltage (Vout). Additional circuitry must be added to cancel the effects of charge injection. In small signal applications this may make the delivery an output voltage that accurately reflects the input voltage almost impossible.

Switching time is a critical function in an analog switch. If the switch operates in a “make before break” mode, meaning the new signal is switched in prior to removing the incumbent signal, there will be a time when Vin1 is shorted to Vin2. Depending on the nature of Vin1 and Vin2, this could be an unacceptable condition and minimizing the duration of the short is imperative. If the switch operates in a “break before make” mode, meaning that the incumbent signal is removed prior to switching the new signal, the output of the analog switch will go to an indeterminate value for some time. This out of control condition may make recovery of the controlled output difficult and should be limited to as short a time as possible. This is yet another situation that requires additional circuitry to counteract a transient determined by any uncancelled charge injection.

Thus, a need still remains for an integrated circuit system for analog switching, that can alleviate the switching time constraint, maintain control of the output signal and prevent the shorting of the input signals. In view of the demand for an increased number of functions in the standard package formats, it is increasingly critical that answers be found to these problems. In view of the ever-increasing commercial competitive pressures, along with growing consumer expectations and the diminishing opportunities for meaningful product differentiation in the marketplace, it is critical that answers be found for these problems. Additionally, the need to save costs, improve efficiencies and performance, and meet competitive pressures, adds an even greater urgency to the critical necessity for finding answers to these problems.

Solutions to these problems have been long sought but prior developments have not taught or suggested any solutions and, thus, solutions to these problems have long eluded those skilled in the art.

### DISCLOSURE OF THE INVENTION

The present invention provides an integrated circuit system including: forming an analog switch including: providing a current source for driving the analog switch, coupling a first source follower to the current source for forming a first input to the analog switch, coupling a second source follower to the current source for forming a second input to the analog switch, and coupling a switch to the first source follower and the second source follower for selecting the first input, the second input, or a combination thereof; and selecting a voltage output signal from the first source follower, the second source follower, or a combination thereof including isolating the first input from the second input.

Certain embodiments of the invention have other aspects in addition to or in place of those mentioned above. The aspects will become apparent to those skilled in the art from a reading of the following detailed description when taken with reference to the accompanying drawings.

### BRIEF DESCRIPTION OF THE DRAWINGS

FIG. 1 is a schematic diagram of an integrated circuit system for analog switching, in an embodiment of the present invention;

FIG. 2 is a functional block diagram of an integrated circuit application of the integrated circuit system for analog switching, of FIG. 1;

FIG. 3 is a system level view of a device that includes the integrated circuit system for analog switching; and

FIG. 4 is a flow chart of an integrated circuit system for using the integrated circuit system for analog switching in an embodiment of the present invention.

### BEST MODE FOR CARRYING OUT THE INVENTION

The following embodiments are described in sufficient detail to enable those skilled in the art to make and use the invention. It is to be understood that other embodiments would be evident based on the present disclosure, and that process or mechanical changes may be made without departing from the scope of the present invention.

In the following description, numerous specific details are given to provide a thorough understanding of the invention. However, it will be apparent that the invention may be practiced without these specific details. In order to avoid obscuring the present invention, some well-known circuits, system configurations, and process steps are not disclosed in detail. Likewise, the drawings showing embodiments of the system are semi-diagrammatic and not to scale and, particularly, some of the dimensions are for the clarity of presentation and are shown greatly exaggerated in the drawing Figures. Where multiple embodiments are disclosed and described, having some features in common, for clarity and ease of illustration, description, and comprehension thereof, similar and like features one to another will ordinarily be described with like reference numerals.

For expository purposes, the term “horizontal” as used herein is defined as a plane parallel to the plane or surface of the integrated circuit substrate, regardless of its orientation. The term “vertical” refers to a direction perpendicular to the horizontal as just defined. Terms, such as “above”, “below”, “bottom”, “top”, “side” (as in “sidewall”), “higher”, “lower”, “upper”, “over”, and “under”, are defined with respect to the horizontal plane. The term “on” means there is direct contact among elements. The term “system” as used herein means and refers to the method and to the apparatus of the present invention in accordance with the context in which the term is used. The term “processing” as used herein includes stamping, forging, patterning, exposure, development, etching, cleaning, and/or removal of the material or laser trimming as required in forming a described structure.

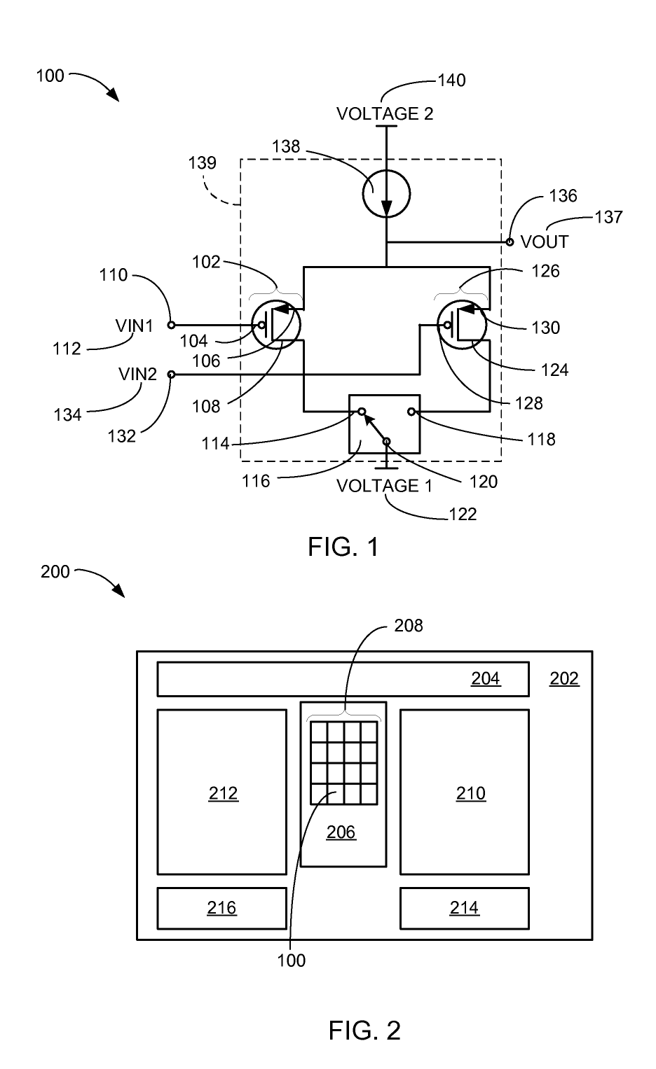

Referring now to FIG. 1, therein is shown a schematic diagram of an integrated circuit system 100 for analog switching, in an embodiment of the present invention. The schematic diagram of the integrated circuit system 100 depicts a first source follower 102, such as a Field Effect Transistor (FET) or a p-channel FET, having a first gate 104, a first source 106, and a first drain 108. The first gate 104 may be electrically connected to a first input node 110. The first input node 110 may be the connection point for a first signal 112, such as VIN1.

The first drain 108 may be electrically connected to a first connection point 114 of a switch 116. The switch 116, such as a single pole double throw switch, may have a second connection point 118 and a pole 120 for connecting a first control voltage 122. The first control voltage 122 may be a ground potential or Vss. The second connection point 118 may be electrically connected to a second drain 124 of a second source follower 126, such as a Field Effect Transistor (FET) or a p-channel FET, which may also have a second gate 128 and a second source 130.

The second gate 128 may be electrically connected to a second input node 132. The second input node 132 may be the connection point for a second signal 134, such as VIN2. The first source 106 and the second source 130 may be electrically connected to each other, a voltage output node 136, and a current source 138. The current source 138 may also be electrically connected to a second control voltage 140, such as a positive voltage or Vdd. The current source 138 may drive the voltage output node 136 by supplying a current the first source follower 102 and the second source follower 126.

The first source follower 102 and the second source follower 126 may be configured as an analog multiplexer. If the pole 120, of the switch 116, is coupled to the first connection point 114, as shown in FIG. 1, the voltage output node 136 may correspond to the first signal 112. This is by way of an example only and the pole 120 may be coupled to the first connection point 114, the second connection point 118, or a combination thereof.

The switch 116 may be implemented as a “make before break” variety of switch. In this configuration the voltage output node may reflect the combination of the first signal 112 and the second signal 134 while both the first connection point 114 and the second connection point 118 are coupled to the pole 120. When only one of the first connection point 114 or the second connection point 118 is coupled to the pole 120, the voltage output node 136 may provide a voltage out signal 137 that follows the selected signal. Since the first gate 104 and the second gate 128 are electrically isolated from the from the voltage output node 136, the first signal 112 cannot be shorted to the second signal 134.

An analog switch 139 may be formed by the coupling of the first source follower 102, the second source follower 126, the switch 116, and the current source 138. The first gate 104, of the first source follower 102, may act as a first input to the analog switch 139. The second gate 128, of the second source follower 126, may act as a second input to the switch 139. The voltage output node 136 may reflect the first signal 112, the second signal 134, or the combination thereof while isolating the first input from the second input.

It has been discovered that the integrated circuit system 100 for analog switching may be configured as a “make before break” switching system without forming an electrical connection between the first signal 112 and the second signal 134. Since the first signal 112 and the second signal 134 are not shorted during the switching process, there is no critical timing requirement. This may allow the output voltage node 136 to remain under control at all times without affecting the first signal 112 or the second signal 134 and without the use of additional components. In prior art circuits, selecting both the first signal 112 and the second signal 134 may result in the first signal 112 and the second signal 134 being shorted together. Since the switch 116 is coupled to the first control voltage 122, any charge injection from the switching process will return to the power source without being detected in the voltage output node 136.

Referring now to FIG. 2, therein is shown a functional block diagram of an integrated circuit application 200 of the integrated circuit system 100 for analog switching, of FIG. 1. The functional block diagram of the integrated circuit application 200 depicts a semiconductor substrate 202 having an interface block 204 and a data convergence block 206. The data convergence block 206 may have a switch array 208, of the integrated circuit system 100, for coupling a first function 210 or a second function 212 to the interface block 204. The first function 210 and the second function 212 may be the same type of device, such as blocks of memory or digital to analog converters.

The data convergence block 206 may provide the control functions to manage the switch array 208. A first input block 214 and a second input block 216 may couple information from the interface block 204 or from other areas of the integrated circuit application 200. This structure is by way of an example only and the actual implementation of the integrated circuit application 200 may differ.

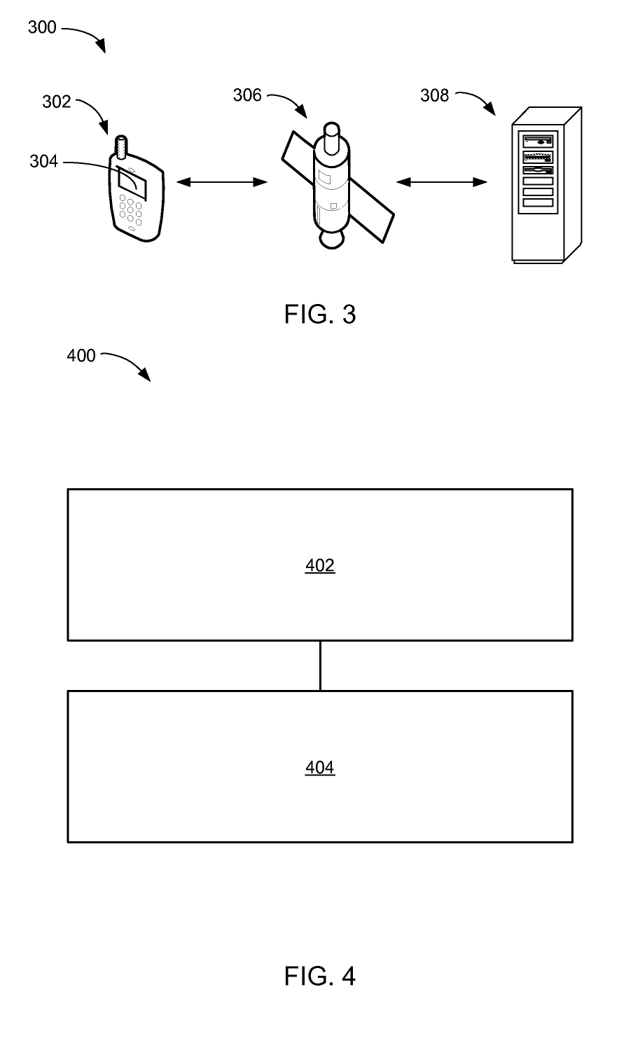

Referring now to FIG. 3, therein is shown a system level view of a device 300 that includes the integrated circuit system 100 for analog switching. The system level view of the device 300 depicts a personal electronic device 302, such as a cellular telephone with a personal video player embedded. The personal electronic device 302 may output information from the integrated circuit application 200, of FIG. 2, in order to utilize a display 304 for two or more functions.

A satellite 306 may utilize the integrated circuit system 100, of FIG. 1, for interfacing redundant system components for system operation or diagnostic functions. There may be several different applications for the integrated circuit system 100 in the satellite 306. The requirement for redundant systems and diagnostic capabilities to support operations in space may be serviced by the integrated circuit application 200. The convergence of multiple data sources on a system bus or a way to compact many data sources into a smaller data bus may be supported by the integrated circuit application 200.

A computer system 308 may utilize the integrated circuit system 100 for minimizing the width of a system bus, or supplying twice as much memory in a single package without increasing the interface width on the system packages. The may also allow interfacing multiple system peripherals through a single interface bus.

It has been unexpectedly discovered that the integrated circuit system 100, of the present invention, may enable shrinking package size and increasing diagnostic interface capabilities at all level of product development.

Referring now to FIG. 4, therein is shown a flow chart of an integrated circuit system 400 for using the integrated circuit system 100 for analog switching in an embodiment of the present invention. The system 400 includes providing a current source for driving the analog switch, coupling a first source follower to the current source for forming a first input to the analog switch, coupling a second source follower to the current source for forming a second input to the analog switch, and coupling a switch to the first source follower and the second source follower for selecting the first input, the second input, or a combination thereof in a block 402; and selecting a voltage output signal from the first source follower, the second source follower, or a combination thereof including isolating the first input from the second input in a block 404.

In greater detail, a system to use the integrated circuit system 100 for analog switching, according to an embodiment of the present invention, is performed as follows:
1. Forming an analog switch including: providing a current source including coupling a second control voltage, coupling a first source follower to the current source including coupling a first source, coupling a second source follower to the current source including coupling a second source, and coupling a switch to the first source follower and the second source follower including coupling a first drain and a second drain to the switch. (FIG. 1) and
2. Selecting a voltage output signal from the first source follower, the second source follower, or a combination thereof including coupling a first control voltage by the switch. (FIG. 1)

It has been discovered that the present invention thus has numerous aspects.

An aspect that has been unexpectedly discovered is that the present invention may remove any common mode requirements in the input of the analog switch by moving the switch to the drain circuit. This references the input voltages to ground.

Another aspect is there is no charge injection in the output voltage due to switching because the switch is located in the drain circuit.

Still another aspect is that the switch may be implemented as a “make before break” switch in order to maintain the control of the output voltage without shorting the input voltages together.

Yet another important aspect of the present invention is that it valuably supports and services the historical trend of reducing costs, simplifying systems, and increasing performance.

These and other valuable aspects of the present invention consequently further the state of the technology to at least the next level.

Thus, it has been discovered that the integrated circuit system for analog switching of the present invention furnishes important and heretofore unknown and unavailable solutions, capabilities, and functional aspects for multiplexing multiple data sources to a single source. The resulting processes and configurations are straightforward, cost-effective, uncomplicated, highly versatile and effective, can be surprisingly and unobviously implemented by adapting known technologies, and are thus readily suited for efficiently and economically manufacturing integrated circuit devices fully compatible with conventional manufacturing processes and technologies. The resulting processes and configurations are straightforward, cost-effective, uncomplicated, highly versatile, accurate, sensitive, and effective, and can be implemented by adapting known components for ready, efficient, and economical manufacturing, application, and utilization.

While the invention has been described in conjunction with a specific best mode, it is to be understood that many alternatives, modifications, and variations will be apparent to those skilled in the art in light of the aforegoing description. Accordingly, it is intended to embrace all such alternatives, modifications, and variations that fall within the scope of the included claims. All matters hithertofore set forth herein or shown in the accompanying drawings are to be interpreted in an illustrative and non-limiting sense.

What is claimed is:

1. An integrated circuit system comprising:
forming an analog switch including:
providing a current source for driving the analog switch,
coupling a first source follower to the current source for forming a first input to the analog switch,
coupling a second source follower to the current source for forming a second input to the analog switch, and
coupling a switch to the first source follower and the second source follower for selecting the first input, the second input, or a combination thereof; and
selecting a voltage output signal from the first source follower, the second source follower, or a combination thereof including isolating the first input from the second input.

2. The system as claimed in claim 1 wherein selecting the voltage output signal includes:
gating a first signal through the first source follower for forming the voltage output signal;
gating a second signal through the second source follower for forming the voltage output signal; and
driving a voltage output node by selecting the first signal, the second signal, or the combination thereof for activating the current source.

3. The system as claimed in claim 1 wherein selecting the voltage output signal includes coupling a first control voltage through the switch to the first source follower, the second source follower, or the combination thereof for activating the current source.

4. The system as claimed in claim 1 further comprising:
providing a substrate for forming the analog switch;
forming a first function on the substrate;
forming a second function on the substrate; and
driving an interface block by the analog switch selecting the first function, the second function, or the combination thereof.

5. The system as claimed in claim 1 further comprising fabricating an integrated circuit application having the analog switch for assembling a device.

6. An integrated circuit system comprising:
forming an analog switch including:
providing a current source for driving the analog switch including coupling a second control voltage,
coupling a first source follower to the current source including coupling a first source for forming a first input to the analog switch,
coupling a second source follower to the current source including coupling a second source for forming a second input to the analog switch, and
coupling a switch to the first source follower and the second source follower for selecting the first input, the second input, or a combination thereof including coupling a first drain and a second drain to the switch; and
selecting a voltage output signal from the first source follower, the second source follower, or a combination thereof including isolating the first input from the second input by coupling a first control voltage through the switch.

7. The system as claimed in claim 6 wherein selecting the voltage output signal includes:
gating a first signal through the first source follower for forming the voltage output signal including driving a first gate;
gating a second signal through the second source follower for forming the voltage output signal including driving a second gate; and
driving a voltage output node by selecting the first signal, the second signal, or the combination thereof for activating the current source including coupling the first drain, the second drain, or the combination thereof to the first control voltage.

8. The system as claimed in claim 6 wherein coupling the first control voltage through the switch including providing a make before break switch for controlling the output voltage signal.

9. The system as claimed in claim 6 further comprising:
providing a substrate for forming the analog switch including forming a switch array;
forming a first function on the substrate including forming a memory or a digital to analog converter;
forming a second function on the substrate including forming a memory or a digital to analog converter; and
driving an interface block by the analog switch selecting the first function, the second function, or the combination thereof including providing a data convergence block for controlling the switch array.

10. The system as claimed in claim 6 further comprising fabricating an integrated circuit application having the analog switch for assembling a device including assembling a personal electronic device, a satellite, or a computer system.

11. An integrated circuit system comprising:
an analog switch including:
a current source for driving the analog switch,
a first source follower coupled to the current source for forming a first input to the analog switch,
a second source follower coupled to the current source for forming a second input to the analog switch, and
a switch coupled to the first source follower and the second source follower for selecting the first input, the second input, or a combination thereof; and
a voltage output node driven from the first source follower, the second source follower, or a combination thereof includes the first input isolated from the second input.

12. The system as claimed in claim 11 wherein the voltage output node driven includes:
a first signal gated through the first source follower for forming the voltage output signal;
a second signal gated through the second source follower for forming the voltage output signal; and
the voltage output node driven by the first signal, the second signal, or the combination thereof selected for activating the current source.

13. The system as claimed in claim 11 wherein the voltage output node driven includes a first control voltage coupled through the switch to the first source follower, the second source follower, or the combination thereof for activating the current source.

14. The system as claimed in claim 11 further comprising:
a substrate having the analog switch formed thereon;
a first function formed on the substrate;
a second function formed on the substrate; and
an interface block driven by the analog switch with the first function, the second function, or the combination thereof selected.

15. The system as claimed in claim 11 further comprising a device assembled includes an integrated circuit application with the analog switch therein.

16. The system as claimed in claim 11 further comprising:
a second control voltage coupled to the current source for driving the analog switch;
a first source coupled to the current source for forming a first input to the analog switch;
a second source coupled to the current source for forming a second input to the analog switch;
a first drain and a second drain coupled to the switch for selecting the first input, the second input, or the combination thereof; and
a first control voltage coupled through the switch.

17. The system as claimed in claim 16 wherein a voltage output node driven includes:
a first signal gated through the first source follower for forming the voltage output signal includes a first gate driven;
a second signal gated through the second source follower for forming the voltage output signal includes a second gate driven; and
the voltage output node driven by the first signal, the second signal, or the combination thereof selected for activating the current source includes the first drain, the second drain, or the combination thereof coupled to the first control voltage.

18. The system as claimed in claim 16 wherein the first control voltage coupled through the switch for controlling the output voltage signal includes a make before break switch provided.

19. The system as claimed in claim 16 further comprising:
a substrate having the analog switch formed thereon includes a switch array formed;
a first function formed on the substrate includes a memory or a digital to analog converter;
a second function formed on the substrate includes a memory or a digital to analog converter; and
an interface block driven by the analog switch with the first function, the second function, or the combination thereof selected includes a data convergence block for controlling the switch array.

20. The system as claimed in claim 16 further comprising a device assembled includes an integrated circuit application with the analog switch therein includes a personal electronic device, a satellite, or a computer system assembled.
